(19) United States
(12) Patent Application Publication
(10) Pub. No.: US 2026/0074685 A1
(43) Pub. Date: Mar. 12, 2026

(54) MANAGING ENERGY CONSUMPTION OF EQUIPMENT USING PULSE WIDTH MODULATION

(71) Applicant: GlacierGrid Inc., San Francisco, CA (US)

(72) Inventors: Manik Varun Suri, San Francisco, CA (US); Aaron Morris Cohen, Westpoint, CT (US); Christophe Niglio, Dillon, MT (US); Chander Chawla, Palo Alto, CA (US); Laurent Parenteau, Saint-Raymond (CA); Lucas Tepman, Venice, CA (US)

(21) Appl. No.: 19/323,733

(22) Filed: Sep. 9, 2025

Related U.S. Application Data
(60) Provisional application No. 63/693,685, filed on Sep. 11, 2024.

(51) Int. Cl. H03K 7/08; F24F 11/64; F24F 11/80; F24F 11/88; F24F 110/12

(52) U.S. Cl. CPC H03K 7/08; F24F 11/64; F24F 11/80; F24F 11/88; F24F 2110/12

(57) ABSTRACT

A system uses pulse width modulation (PWM) to control the power demand of an equipment. The system receives a thermostat setting for controlling the equipment. The system provides output of the controller to a pulse width modulator. The pulse width modulator causes the signal provided as input to the equipment to be turned off for a portion of a time interval. The portion of cycle during which the signal is turned off is determined based on a duty cycle of the pulse width modulator. The system provides the controller output modulated by the pulse width modulator as input to the equipment. The modulated output of the controlled causes the demand of the equipment to decrease.

### CROSS-REFERENCE TO RELATED APPLICATION

This application claims the benefit of U.S. Provisional Application No. 63/693,685, filed on Sep. 11, 2024, which is incorporated by reference in its entirety.

### FIELD OF INVENTION

The disclosure relates to energy management in general and more specifically to pulse width modulation (PWM) based energy management of equipment such as heating, ventilation and air conditioning (HVAC) equipment.

### BACKGROUND

Several facilities use equipment that consume power, for example, air conditioning equipment, refrigeration equipment, heating equipment, HVAC equipment, and so on. A facility may have periods of peak load when various types of equipments of the facility consume large amount of power at the same time. High consumption of power during peak hours can strain the power grid and increase likelihood of power outages and blackouts if the power supply is unable to meet the peak demands of power. Power companies typically charge more for facilities with high peak consumption or power. As a result, facilities try to reduce the energy consumed during peak hours. Reducing peak energy consumption typically results in significant savings in the cost of energy consumed by the equipment of the facility.

### SUMMARY

A system uses a pulse width modulation of power to control demand of an equipment, according to an embodiment. The system receives a thermostat setting for controlling the equipment for changing temperature of space controlled by the equipment. The equipment is controlled by a feedback loop comprising a controller providing a signal for causing the temperature of the space controlled by the equipment to be maintained to a value based on the thermostat setting.

The system provides output of the controller to a pulse width modulator. The pulse width modulator causes the equipment to be turned off for a portion of a time interval. The portion of cycle during which the signal is turned off is determined based on a duty cycle of the pulse width modulator. The system provides 430 the controller output modulated by the pulse width modulator as input to the equipment. The modulated output of the controller causes the demand of the equipment to decrease. The demand represents a moving average of power consumption of the equipment determined over a time interval of a predetermined length (e.g., every 15 minutes). Accordingly, the system uses pulse width modulation to reduce the power consumption of the equipment.

Embodiments of a computer readable storage medium store instructions for performing the steps of the above methods. Embodiments of a computer system comprise one or more computer processors and a computer readable storage medium that stores instructions for performing the steps of the above methods.

### BRIEF DESCRIPTION OF DRAWINGS

The disclosed embodiments have other advantages and features which will be more readily apparent from the detailed description, the appended claims, and the accompanying figures (or drawings). A brief introduction of the figures is below.

FIG. 1 shows the overall system environment for pulse width modulation based energy management, according to an embodiment.

FIG. 2A shows a system executing an HVAC without a PWM module, according to an embodiment.

FIG. 2B shows a signal waveform generated by the system of FIG. 2A running an HVAC, according to an embodiment.

FIG. 3A shows a system executing an HVAC with a PWM module, according to an embodiment.

FIG. 3B shows a signal waveform generated by the system of FIG. 3A running an HVAC, according to an embodiment.

FIG. 4 is a flowchart of a process for using PWM to control demand of an equipment, according to an embodiment.

FIG. 5 is a block diagram illustrating components of an example machine able to read instructions from a machine-readable medium and execute them in a processor (or controller).

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

The features and advantages described in the specification are not all inclusive and in particular, many additional features and advantages will be apparent to one of ordinary skill in the art in view of the drawings, specification, and claims. Moreover, it should be noted that the language used in the specification has been principally selected for readability and instructional purposes, and may not have been selected to delineate or circumscribe the disclosed subject matter.

### DETAILED DESCRIPTION

A facility may use various types of equipment that consumes power, for example, refrigerator, heater, machinery, medical equipment, and so on. Examples of facilities include restaurants, hotels, factories, residential buildings, hospitals, and so on. The power or energy consumed by equipment of a facility is referred to as demand. Demand is measured as the average power consumed in a time interval, for example, in a 15 minute period. Demand of a facility may be determined by dividing the power consumed in a time interval by the length of the time interval.

If multiple equipment in a facility are turned on at the same time, the demand or peak power of the facility is higher. Some equipment such as HVAC (Heating, Ventilation, and Air Conditioning) system may include multiple components such as a compressor, fans, and so on. If multiple components are turned on at the same time, the HVAC unit consumes more power. Similarly, the facility may have various equipment that consume power such as fan, lights, and so on.

A utility company measures power across various time intervals, e.g., different 15 minute intervals. The peak power is the maximum power determined over a larger time interval, for example, over a month. If a facility has high peak power, the facility may be charged at a higher rate whereas if the facility has low peak power, the facility is charged at a lower rate.

The system uses a pulse width modulator to ensure that the peak power is reduced during a time interval by turning off some of the equipment for at least a portion of the time interval. According to an embodiment, the pulse width modulator is a software module. The pulse width modulator may also be referred to as a PWM module. A pulse width modulator modifies the signal that controls the equipment to be shaped as a pulse within each time interval. Accordingly, the signal is on for a duration of each time interval and off for the remaining time interval. The fraction (or percentage) of each interval during which the signal is ON is represented as the duty cycle of the pulse width modulator. By modifying the pulse width of the PWM signal, the pulse width modulator controls the equipment such as HVAC unit to perform peak shaving.

The use of the pulse width modulator as disclosed herein results in cost savings by reducing the demand by a fraction. However, the savings come at the cost of comfort since the equipment is shut off for a fraction of each time interval. Accordingly, for example, if the equipment is designed to cool a space, the equipment will be off for a portion of each time interval and may result in increase in temperature of the space to a value above the thermostat setting. Accordingly, even if a user wants the space to be set at a particular temperature using the thermostat, the temperature of the space may go above the set temperature, resulting in possible discomfort to the user/users in the space.

### Overall System Environment

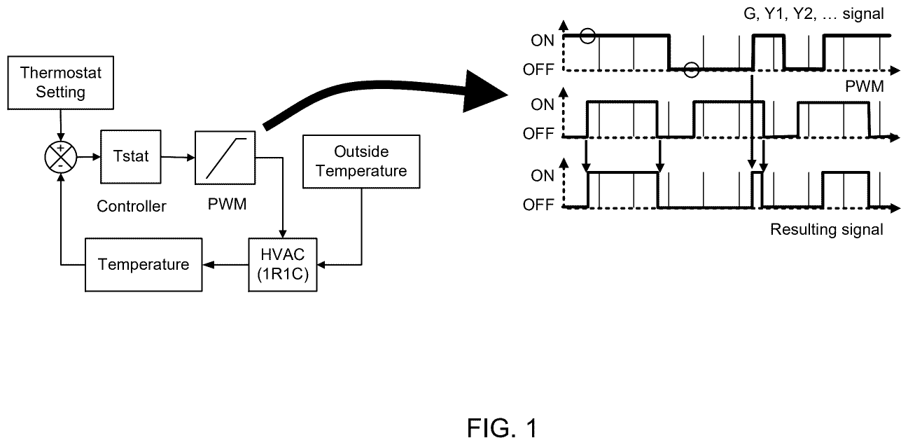

FIG. 1 shows the overall system environment for pulse width modulation based energy management, according to an embodiment. The overall system shown in FIG. 1 represents a control system. A comparator compares thermostat setting to temperature of equipment such as HVAC temperature. The output of the comparator is fed into a controller (Tstat or thermostat). The output of the controller is provided as input to a pulse width modulator that controls the HVAC system. The signal provided to the HVAC determines whether the HVAC unit makes the surrounding cooler by extracting heat from the surroundings or makes the surroundings hotter by providing heat to the surroundings.

According to some embodiments the pulse width modulator is integrated into the thermostat. The pulse width modulator modifies the thermostat output to perform peak shaving. The signals G, Y1, Y2, . . . shown in FIG. 1 are output by the thermostat. When the signal is high, the signal may turn a particular device on (e.g., a fan) and when the signal is low, it turns the device off. For example, signal G may be provided as input to a fan, signal Y1 may be provided as input to compressor stage 1, signal Y2 may be provided as input to compressor stage 2, and so on. Whenever the equipment is turned on by the signal, the equipment consumes power, for example, by using a constant current to run the equipment.

The pulse width modulator masks the signals generated by the thermostat (to perform a logical AND operator) with a pulse signal to generate the resulting signal. The power consumption of the equipment may also vary based on environment, for example, the outside temperature. The pulse width modulator modifies the signal that controls the HVAC unit or any other equipment. The pulse width modulator modifies the control signal to be shaped as a pulse within each time interval by turning the signal on for a duration of each time interval and off for the remaining time interval. By modifying the pulse width of the signal, the pulse width modulator controls the equipment such as HVAC unit to perform peak shaving.

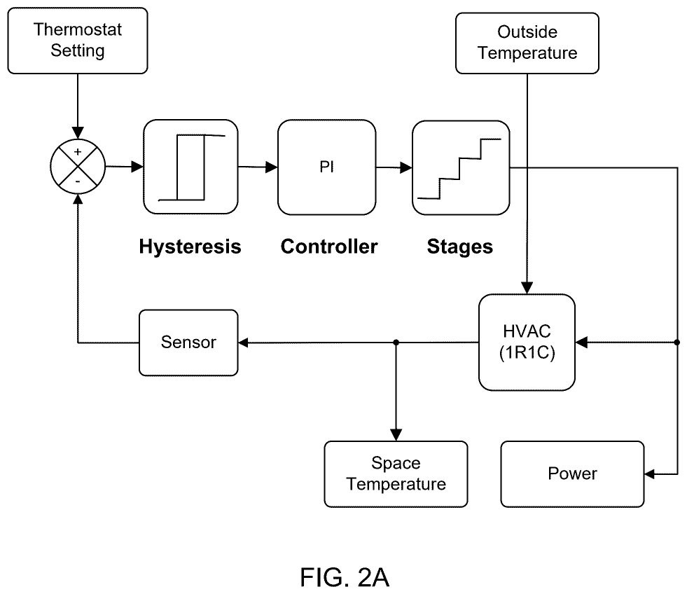

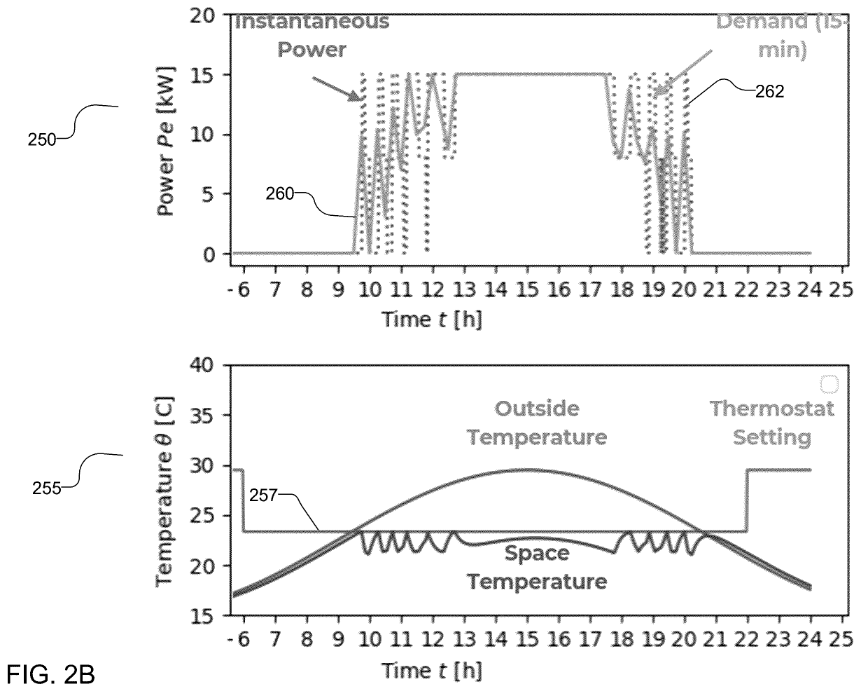

FIG. 2A shows a system executing an HVAC without a pulse width modulator. The HVAC simulation may be replaced by an actual HVAC system using the configuration shown in FIG. 2A. The HVAC as illustrated in FIG. 2A has two stages, a first stage of 8 kW and a second stage of 15 kW. If the error between the outside temperature and the space temperature is within a threshold value, the HVAC stage 1 is active and if the error between the outside temperature and the space temperature becomes above the threshold value, the HVAC stage 2 becomes active.

FIG. 2B shows a signal waveform generated by the system of FIG. 2A running an HVAC, according to an embodiment. The chart 255 shows a curve illustrating the variations in temperatures with respect to time including the outside temperature and the space temperature (e.g., temperature of a room in a facility that has temperature controlled by HVAC). The outside temperature increases with time and then decreases over a time interval. The temperature of the space is controlled to stay below a threshold value 257. The threshold 257 is determined by the setting of the thermostat. If the outside temperature increases, the space temperature also increases if the outside temperature is below the threshold value 257. If the space temperature reaches the threshold 257, the thermostat causes the HVAC to start cooling the space, resulting in a drop in the space temperature. However, the space temperature drops only by a specific amount and then again increases due to the increasing outside temperature. This cycle repeats as the outside temperature keeps increasing.

The chart 250 shows the corresponding variation of power with respect to time. The power chart 250 shows instantaneous power 262 and demand 260 that represents the average power over a predetermined time interval (i.e., a rolling average of the instantaneous power 262 over time intervals of a fixed length, e.g., over 15 minute time intervals).

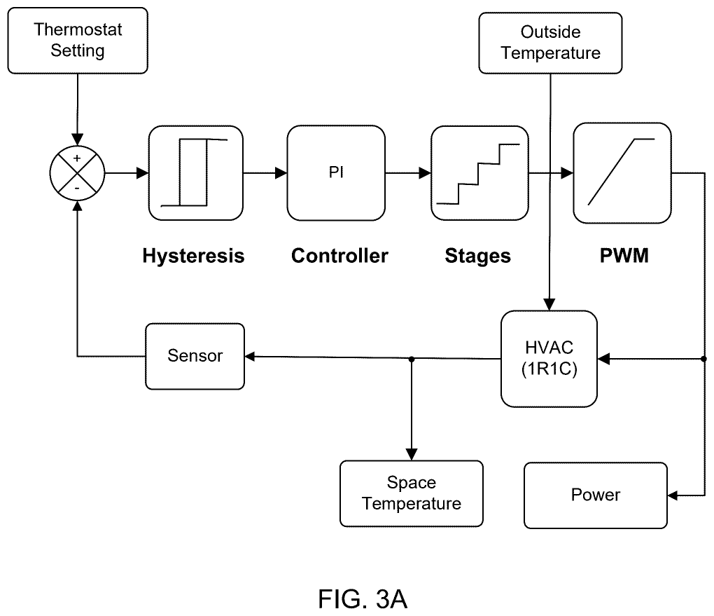

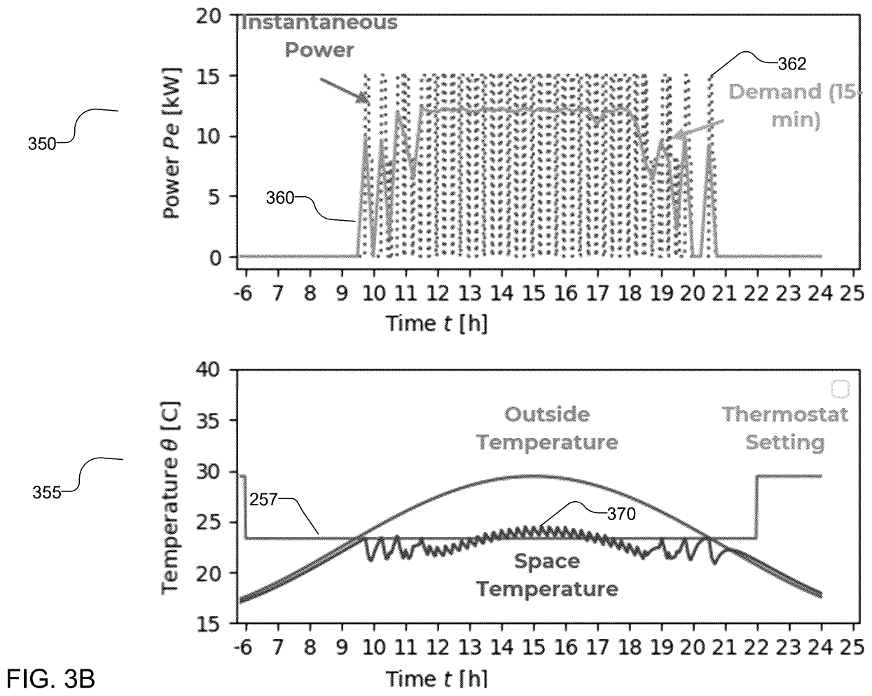

FIG. 3A shows a system executing an HVAC with a PWM module, according to an embodiment. Accordingly, the signal that is provided to the HVAC to control the HVAC components is provided as input to the pulse width modulator and the output of the pulse width modulator provided as input to the HVAC unit. The pulse width modulator uses a pulse that switches off the input to the HVAC unit for 80% of the time. For example, for a time window of T units, the pulse width modulator provides the signal input to the HVAC unit for 0.8*T units and turns off the signal for the remaining 0.2*T units of time. The pulse width modulator is configured on an open loop manner since there is no feedback to the pulse width modulator.

According to an embodiment, the period of the pulse of the pulse width modulator matches the period used for calculating demand charge, for example, both are 15 minutes. This results in reducing the demand. The system shown in FIG. 3B has a close loop on the temperature and there is an open loop with fixed value of pulse width modulator at 80% of time interval independent of other factors. Accordingly, the duty cycle of the PWM is 80%. A duty cycle is the fraction of one period when a system or signal is active.

FIG. 3B shows a signal waveform generated by the system of FIG. 3A running an HVAC, according to an embodiment. As shown in FIG. 3B, the chart 355 shows variation of temperature (outside and space temperature) with respect to time and chart 350 shows power and demand. As shown in FIG. 3B, the demand shown by chart 360 is below the highest instantaneous power value shown by the curve 362. This is different from the chart 250 that shows the demand 260 to match the highest instantaneous power value 262. The PWM module throttles the system by providing a control on the signal that is provided as input to the HVAC. Since the HVAC is shut off during a part of each time interval, the space temperature shown by 370 does exceed the value at which the thermostat is set for a portion of each time interval.

According to an embodiment, feedback is provided to the PWM module to determine the duty cycle of the PWM module, i.e., to control the percentage of a time interval for which the signal is kept on vs. off. The lower the duty cycle is, the less regulation of the temperature is performed, i.e., the temperature is more likely to exceed the thermostat setting. Accordingly, the facility saves on peak power consumption at the cost of making the facility a little less regulated, for example, hotter than required by the thermostat. Reducing the peak consumption typically results in significant savings in the power costs of the facility.

According to an embodiment, PWM is implemented by applying switches to each signal that needs to be controlled and controlling the switches using LoRaWAN (long range wide area networking) protocol. Other embodiments include any switch that can be controlled. The control may be remote, i.e., via a networking signal such as a wireless signal. Multiple PWM modules may be implemented by a facility, for example, for different equipment within the facility. The different PWM modules may be synchronized or work independent of each other. The multiple PWM units may be provided a schedule of when to turn their respective units on and when to turn them off and the PWM modules act as if they were synchronized even though they are working independent of each other. According to an embodiment, a centralized control unit sends signals to the different PWM modules to explicitly synchronize them. The synchronization of various PWM modules may ensure that the different units are turned ON/OFF during different parts of the same time interval. Accordingly, the ON/OFF times of different PWM modules are staggered across each time interval.

The PWM module acts as an actuator that allows control of the equipment such as HVAC, Air Conditioning equipment, and so on. Various techniques can be used to determine the duty cycle of the equipment, for example, artificial intelligence technique may be used to predict when an equipment is likely to reach peak usage, and so on. These techniques determine the duty cycle which is then implemented using the PWM module.

According to an embodiment, the system is implemented as a switch that is connected between a thermostat and a contractor. A contactor on an equipment such as HVAC or AC unit is typically located in the equipment's outdoor unit such as a condenser unit. The contractor provides power to components such as the compressor and condenser fan and turns the equipment on and off. A contactor can fail electrically or mechanically.

### Overall Process

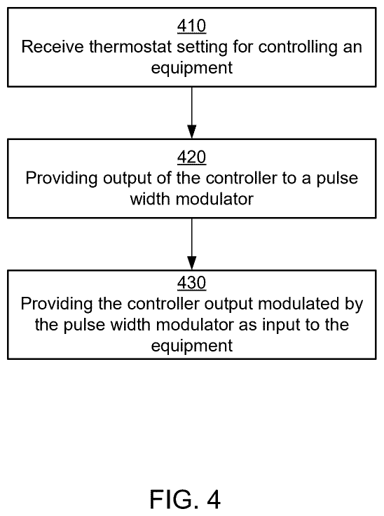

FIG. 4 is a flowchart of a process for using PWM to control demand of an equipment, according to an embodiment. The system receives 410 a thermostat setting for controlling the equipment for changing temperature of space controlled by the equipment. The equipment is controlled by a feedback loop comprising a controller providing a signal for causing the temperature of the space controlled by the equipment to be maintained to a value based on the thermostat setting. The system provides 420 output of the controller to a PWM module. The PWM module causes the signal provided as input to the equipment to be turned off for a portion of a time interval. The portion of cycle during which the signal is turned off is determined based on a duty cycle of the PWM module. The system provides 430 the controller output modulated by the PWM module as input to the equipment. The modulated output of the controlled causes the demand of the equipment to decrease. The demand represents a moving average of power consumption of the equipment determined over a time interval of a predetermined length (e.g., every 15 minutes).

The equipment being controlled may be an air conditioning equipment, a heating equipment, a refrigeration equipment, or a heating, ventilation, and air conditioning (HVAC) equipment.

According to an embodiment, the equipment is used in a facility that also includes other equipment. The duty cycle of the PWM module is determined based on one or more other equipments of the facility.

According to an embodiment, the system determines a time of peak power consumption of a facility. The system modifies the duty cycle of the PWM module based on the time of peak power consumption. The system may predict the peak power consumption using a machine learning based model. The machine learning based model receives input features describing the system environment including the equipment being controlled as well as other equipment in the facility that may affect peak power consumption. The input may also receive recent history of the equipment, for example, a vector representing the power consumption at various time intervals in a recent past. According to an embodiment, the machine learning based model is trained using reports based on power consumption that were previously generated.

According to an embodiment, the system receives a measure of a temperature of the space controlled by the equipment and determining the duty cycle of the PWM module based on the temperature of the space controlled by the equipment.

According to an embodiment, the facility includes one or more other equipments. The system staggers the part of each time interval during which the power of each equipment is shut off by the PWM module. For example, if there are three different equipments in a facility, the first equipment may be shut off during an initial part of the time interval, the second equipment may be shut off during a final part of the time interval, and the third equipment is shut off during the middle of the time interval.

### Computing Machine Architecture

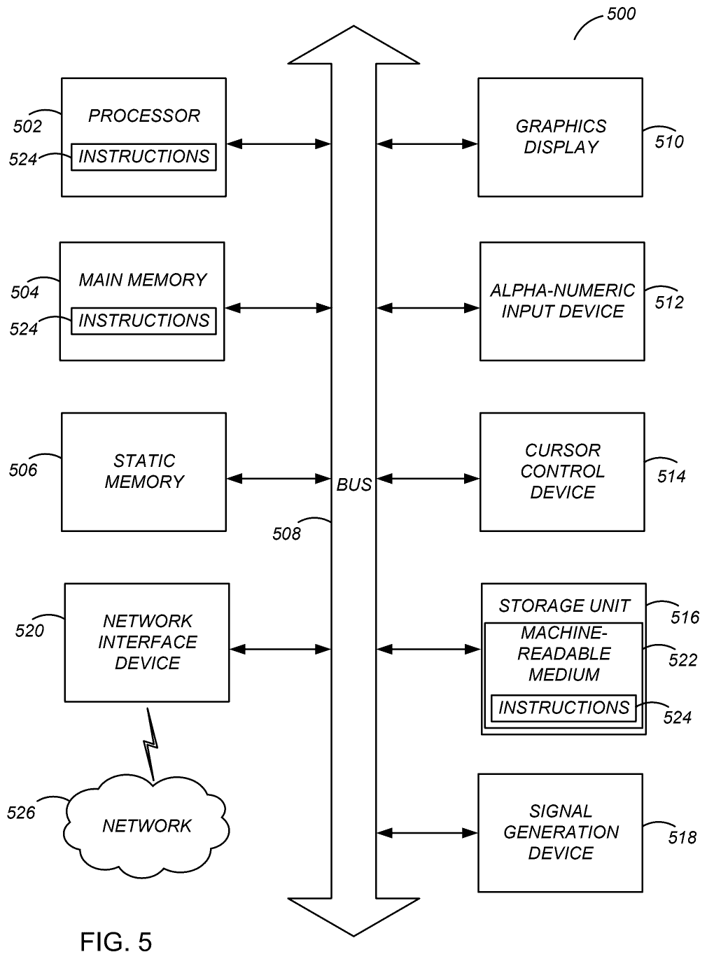

FIG. 5 is a block diagram illustrating components of an example machine able to read instructions from a machine-readable medium and execute them in a processor (or controller). Specifically, FIG. 5 shows a diagrammatic representation of a machine in the example form of a computer system 500 within which instructions 524 (e.g., software) for causing the machine to perform any one or more of the methodologies discussed herein may be executed. In alternative embodiments, the machine operates as a standalone device or may be connected (e.g., networked) to other machines. In a networked deployment, the machine may operate in the capacity of a server machine or a client machine in a server-client network environment, or as a peer machine in a peer-to-peer (or distributed) network environment.

The machine may be a server computer, a client computer, a personal computer (PC), a tablet PC, a set-top box (STB), a personal digital assistant (PDA), a cellular telephone, a smartphone, a web appliance, a network router, switch or bridge, or any machine capable of executing instructions 524 (sequential or otherwise) that specify actions to be taken by that machine. Further, while only a single machine is illustrated, the term “machine” shall also be taken to include any collection of machines that individually or jointly execute instructions 524 to perform any one or more of the methodologies discussed herein.

The example computer system 500 includes a processor 502 (e.g., a central processing unit (CPU), a graphics processing unit (GPU), a digital signal processor (DSP), one or more application specific integrated circuits (ASICs), one or more radio-frequency integrated circuits (RFICs), or any combination of these), a main memory 504, and a static memory 506, which are configured to communicate with each other via a bus 508. The computer system 500 may further include graphics display unit 510 (e.g., a plasma display panel (PDP), a liquid crystal display (LCD), a projector, or a cathode ray tube (CRT)). The computer system 500 may also include alphanumeric input device 512 (e.g., a keyboard), a cursor control device 514 (e.g., a mouse, a trackball, a joystick, a motion sensor, or other pointing instrument), a storage unit 516, a signal generation device 518 (e.g., a speaker), and a network interface device 520, which also are configured to communicate via the bus 508.

The storage unit 516 includes a machine-readable medium 522 on which is stored instructions 524 (e.g., software) embodying any one or more of the methodologies or functions described herein. The instructions 524 (e.g., software) may also reside, completely or at least partially, within the main memory 504 or within the processor 502 (e.g., within a processor's cache memory) during execution thereof by the computer system 500, the main memory 504 and the processor 502 also constituting machine-readable media. The instructions 524 (e.g., software) may be transmitted or received over a network 526 via the network interface device 520.

While machine-readable medium 522 is shown in an example embodiment to be a single medium, the term “machine-readable medium” should be taken to include a single medium or multiple media (e.g., a centralized or distributed database, or associated caches and servers) able to store instructions (e.g., instructions 524). The term “machine-readable medium” shall also be taken to include any medium that is capable of storing instructions (e.g., instructions 524) for execution by the machine and that cause the machine to perform any one or more of the methodologies disclosed herein. The term “machine-readable medium” includes, but not be limited to, data repositories in the form of solid-state memories, optical media, and magnetic media.

### Alternative Embodiments

It is to be understood that the figures and descriptions of the present invention have been simplified to illustrate elements that are relevant for a clear understanding of the present invention, while eliminating, for the purpose of clarity, many other elements found in a typical system. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Some portions of above description describe the embodiments in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

Some embodiments may be described using the expression “coupled” and “connected” along with their derivatives. It should be understood that these terms are not intended as synonyms for each other. For example, some embodiments may be described using the term “connected” to indicate that two or more elements are in direct physical or electrical contact with each other. In another example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the invention. This description should be read to include one or at least one and the singular also includes the plural unless it is obvious that it is meant otherwise.

Upon reading this disclosure, those of skill in the art will appreciate still additional alternative structural and functional designs for a system and a process for generating reports based on instrumented software through the disclosed principles herein. Thus, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope defined in the appended claims.

What is claimed is:

1. A computer-implemented method, comprising:
receiving a thermostat setting for controlling an equipment for changing temperature of a space associated with the equipment, the equipment controlled by a signal provided as input to the equipment;
generating a modulated signal based on the thermostat setting by performing pulse width modulation of the signal provided as input to the equipment by causing the signal to be turned off for a portion of time interval and turned on for remaining time interval, the portion of time interval determined based on a duty cycle; and
providing the modulated signal as input to the equipment, causing a demand of the equipment to decrease, wherein the demand is a moving average of power consumption of the equipment determined over a time interval of a predetermined length.

2. The computer-implemented method of claim 1, wherein the equipment is one of:
an air conditioning equipment,
a heating equipment,
a refrigeration equipment, or
a heating, ventilation, and air conditioning (HVAC) equipment.

3. The computer-implemented method of claim 1, further comprising:
determining a time of peak power consumption of a facility; and
modifying the duty cycle based on the time of peak power consumption.

4. The computer-implemented method of claim 3, wherein the time of peak power consumption is predicted using a machine learning based model.

5. The computer-implemented method of claim 1, wherein the equipment is used in a facility comprising one or more other equipments, wherein the duty cycle is determined based on one or more other equipments of the facility.

6. The computer-implemented method of claim 5, wherein the facility includes one or more other equipments, the computer-implemented method further comprising:
staggering the portion of each time interval during which the input provided to each equipment is shut off.

7. The computer-implemented method of claim 1, further comprising:
receiving a measure of a temperature of the space controlled by the equipment; and
determining the duty cycle based on temperature of the space controlled by the equipment.

8. A non-transitory computer readable storage medium storing instructions that when executed by one or more computer processors cause the one or more computer processors to perform steps comprising:
receiving a thermostat setting for controlling an equipment for changing temperature of a space associated with the equipment, the equipment controlled by a signal provided as input to the equipment;
generating a modulated signal based on the thermostat setting by performing pulse width modulation of the signal provided as input to the equipment by causing the signal to be turned off for a portion of time interval and turned on for remaining time interval, the portion of time interval determined based on a duty cycle; and
providing the modulated signal as input to the equipment, causing a demand of the equipment to decrease, wherein the demand is a moving average of power consumption of the equipment determined over a time interval of a predetermined length.

9. The non-transitory computer readable storage medium of claim 8, wherein the equipment is one of:
an air conditioning equipment,
a heating equipment,
a refrigeration equipment, or
a heating, ventilation, and air conditioning (HVAC) equipment.

10. The non-transitory computer readable storage medium of claim 8, wherein the instructions cause the one or more computer processors to further perform steps comprising:
determining a time of peak power consumption of a facility; and
modifying the duty cycle based on the time of peak power consumption.

11. The non-transitory computer readable storage medium of claim 10, wherein the time of peak power consumption is predicted using a machine learning based model.

12. The non-transitory computer readable storage medium of claim 8, wherein the equipment is used in a facility comprising one or more other equipments, wherein the duty cycle is determined based on one or more other equipments of the facility.

13. The non-transitory computer readable storage medium of claim 12, wherein the facility includes one or more other equipments, wherein the instructions cause the one or more computer processors to further perform steps comprising:
staggering the portion of each time interval during which the input provided to each equipment is shut off.

14. The non-transitory computer readable storage medium of claim 8, wherein the instructions cause the one or more computer processors to further perform steps comprising:
receiving a measure of a temperature of the space controlled by the equipment; and
determining the duty cycle based on temperature of the space controlled by the equipment.

15. A computer system comprising:
one or more computer processors; and
a non-transitory computer readable storage medium storing instructions that when executed by one or more computer processors cause the one or more computer processors to perform steps, comprising:
receiving a thermostat setting for controlling an equipment for changing temperature of a space associated with the equipment, the equipment controlled by a signal provided as input to the equipment;
generating a modulated signal based on the thermostat setting by performing pulse width modulation of the signal provided as input to the equipment by causing the signal to be turned off for a portion of time interval and turned on for remaining time interval, the portion of time interval determined based on a duty cycle; and
providing the modulated signal as input to the equipment, causing a demand of the equipment to decrease, wherein the demand is a moving average of power consumption of the equipment determined over a time interval of a predetermined length.

16. The computer system of claim 15, wherein the equipment is one of:
an air conditioning equipment,
a heating equipment,
a refrigeration equipment, or
a heating, ventilation, and air conditioning (HVAC) equipment.

17. The computer system of claim 15, wherein the instructions cause the one or more computer processors to further perform steps comprising:
determining a time of peak power consumption of a facility, wherein the time of peak power consumption is predicted using a machine learning based model; and
modifying the duty cycle based on the time of peak power consumption.

18. The computer system of claim 15, wherein the equipment is used in a facility comprising one or more other equipments, wherein the duty cycle is determined based on one or more other equipments of the facility.

19. The computer system of claim 18, wherein the facility includes one or more other equipments, wherein the instructions cause the one or more computer processors to further perform steps comprising:
staggering the portion of each time interval during which the input provided to each equipment is shut off.

20. The computer system of claim 15, wherein the instructions cause the one or more computer processors to further perform steps comprising:
receiving a measure of a temperature of the space controlled by the equipment; and
determining the duty cycle based on temperature of the space controlled by the equipment.
